(19) United States
(12) Patent Application Publication
(10) Pub. No.: US 2018/0006433 A1
(43) Pub. Date: Jan. 4, 2018

(54) LASER CHIP WITH MULTIPLE OUTPUTS ON COMMON SIDE

(71) Applicant: Mellanox Technologies Silicon Photonics Inc., Monterey Park, CA (US)

(72) Inventors: Dazeng Feng, El Monte, CA (US); Bhavin Bijlani, Glendora, CA (US); Amir Ali Tavallaee, Los Angeles, CA (US); Bradley Jonathan Luff, La Canada Flintridge, CA (US)

(21) Appl. No.: 15/197,066

(22) Filed: Jun. 29, 2016

(51) Int. Cl. H01S 5/20; H01S 5/22; H01S 5/125; H01S 5/02; H01S 3/063; H01S 5/12; H01S 5/10; H01S 3/08; H01S 5/30; H01S 5/028

(52) U.S. Cl. CPC H01S 5/20; H01S 5/3013; H01S 5/22; H01S 5/125; H01S 5/028; H01S 3/0637; H01S 5/1243; H01S 5/101; H01S 5/1003; H01S 3/08; H01S 5/021

(57) ABSTRACT

A laser chip including a laser cavity that produces multiple laser outputs. A laser waveguide guides light through the laser cavity and has multiple output facets. Each of the laser outputs passes through one of the output facets. The laser waveguide guides the laser outputs such that the angle between the exit direction of different laser outputs is less than 180°. The exit direction for a laser output is the direction of propagation of light in the laser waveguide at one of the output facets.

### FIELD

The present invention relates to optical devices and particularly to optical devices that include lasers.

### BACKGROUND

Optical systems often include a laser chip that is attached to an optical device that includes one or more other optical components. The laser chip serves as the source of light signals that are processed by the device. These laser chips typically produce an output from opposing sides of the chip. Generally, one of the outputs is received and processed by the device while the other outputs is not used or is received directly at a light sensor. When one of the outputs is received at a light sensor, the output is generally more powerful than is needed for proper processing of the output signal. As a result, these laser chips are often highly inefficient and there is a need for more efficient optical systems.

### SUMMARY

An optical system includes a laser chip with a laser cavity that produces laser outputs. The laser chip includes lateral sides between a top side and a bottom side. At least two of the laser outputs cross the same lateral side of the laser chip.

Another embodiment of the optical system includes a laser chip with a laser cavity that produces multiple laser outputs. A laser waveguide guides light through the laser cavity and has multiple output facets. Each of the laser outputs passes through one of the output facets. The laser waveguide guides the laser outputs such that the angle between the exit directions of different laser outputs is less than 180°, 100°, or 50°. The exit direction for a laser output is the direction of propagation of the laser output through the laser waveguide at one of the output facets.

### BRIEF DESCRIPTION OF THE FIGURES

FIG. 1A is a top view of an optical system that includes a laser chip on an optical device. The laser chip includes a laser cavity that curved such that multiple outputs from the laser cross the same lateral side of the laser chip.

FIG. 1B is a top view of the optical system of FIG. 1A with the laser cavity modified to include straight regions.

FIG. 1C is a top view of the optical system of FIG. 1A with the laser cavity modified such that the direction of propagation of light at different output facets is not perpendicular to a lateral dimension of the output facets.

FIG. 1D is a top view of the optical system of FIG. 1B with the laser chip modified to include a Distributed Feedback (DFB) laser cavity.

FIG. 1E is a top view of an optical system that includes a laser chip having a laser waveguide constructed such to provide a 90° angle between the direction of propagation of the light in the laser waveguide at different output facets.

FIG. 1F is a top view of the optical system of FIG. 1B modified to include a laser cavity with reflectors that change the direction of the intracavity light in the laser cavity.

FIG. 2A through FIG. 2C illustrate an optical device that is suitable for use in the optical system of FIG. 1A through FIG. 1F. FIG. 2A is a top view of the portion of the optical device that is configured to be attached to the laser chip.

FIG. 2B is a cross section of the optical device taken along the line labeled B in FIG. 2A.

FIG. 2C is a perspective view of a portion of the optical device shown in FIG. 2A.

FIG. 3A through FIG. 3E illustrate a laser chip that is suitable for use with an optical device constructed according to FIG. 2A through FIG. 2C. FIG. 3A is a top view of the laser chip.

FIG. 3B is a cross-section of the laser chip shown in FIG. 3A taken along the line labeled B in FIG. 3A.

FIG. 3C is a cross-section of the laser chip shown in FIG. 3A taken along the line labeled C in FIG. 3A.

FIG. 3D is a cross-section of the laser chip shown in FIG. 3A taken along the line labeled D in FIG. 3A.

FIG. 3E is a bottom view of the laser chip of FIG. 3A.

FIG. 4A through FIG. 4C illustrate assembly of the optical system using an optical device constructed according to FIG. 2A through FIG. 2C and a laser chip constructed according to FIG. 3A through FIG. 3E. The optical device illustrated in FIG. 4A does not show either a cross-sectional view or a side view but instead shows the relative positions of different features of the optical device when looking at a side view of the optical device. In contrast, the laser chip illustrated in FIG. 4A is a cross-sectional view of the laser chip such as the cross section of FIG. 3C.

FIG. 4B is a top view of the assembled system.

FIG. 4C is a cross section of the system shown in FIG. 4B taken along the line labeled C in FIG. 4B.

FIG. 5 is a block diagram of an optical system.

### DESCRIPTION

An optical system includes a laser chip having a laser cavity that produces multiple laser outputs. The laser chip can be a semiconductor laser and can be configured such that the different outputs exit the laser from the same side. As a result, when the laser chip is mounted on an optical device such as a planar optical device, the optical device can concurrently receive and process multiple laser outputs from the laser chip. Accordingly, the system provides a much more efficient use of the output generated by the laser chip. Additionally, since the different outputs can exit from the same side of the laser chip, it is often possible to put an anti-reflective coating on a single side of the laser chip rather than on multiple sides. Accordingly, the laser chip can have reduced manufacturing costs and complexity.

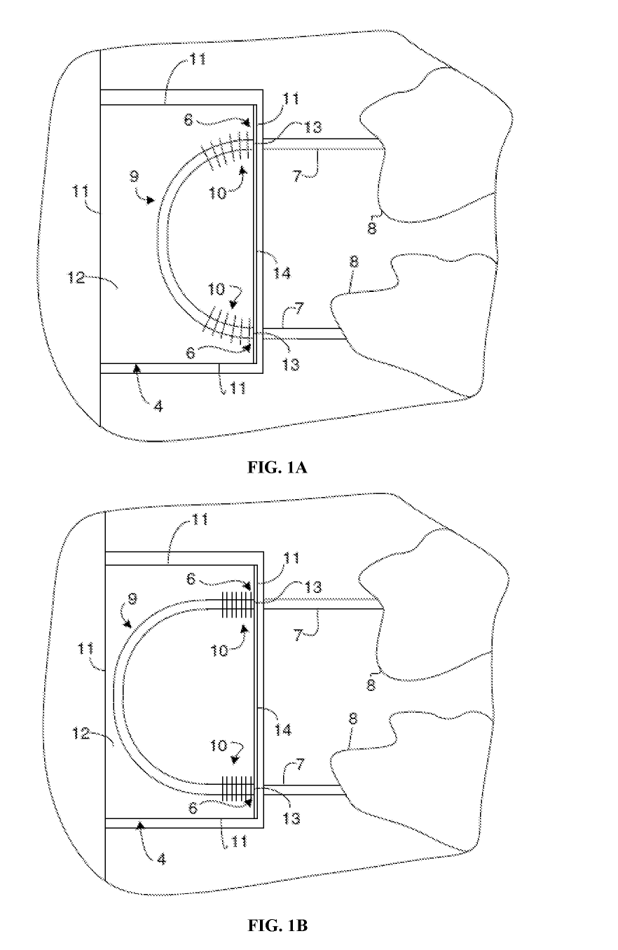

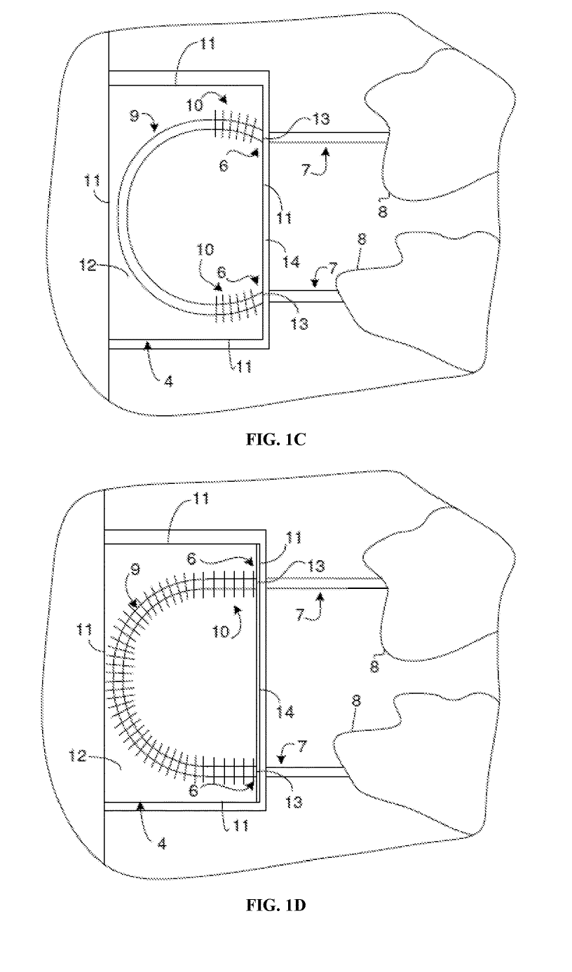

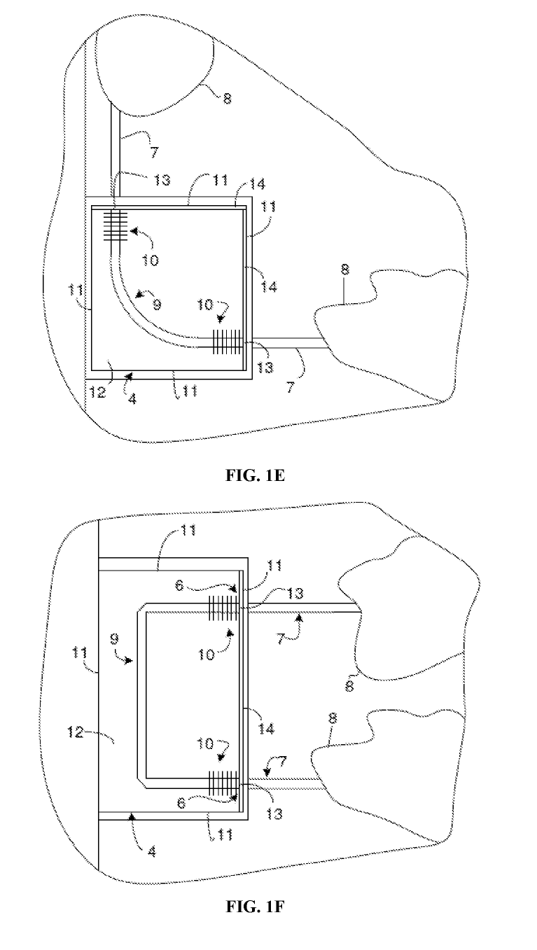

FIG. 1A is a top view of an optical system that includes a laser chip 4 on an optical device. The laser chip 4 includes a laser cavity with two output ports 6 through which different laser outputs exit from the laser chip 4. The laser cavity is arranged such that the optical device receives each of the laser outputs from the laser cavity. For instance, the optical device includes two waveguides 7 and each of the waveguides 7 receives one of the laser outputs. In FIG. 1A, each of the waveguides 7 carries the received light signal to a different optical component 8 on the optical device; however, the waveguides 7 can carry the received light signal to the same optical component.

Examples of optical components 8 that can be included on the optical device include, but are not limited to, one or more components selected from a group consisting of facets through which light signals can enter and/or exit a waveguide, entry/exit ports through which light signals can enter and/or exit a waveguide from above or below the optical device, multiplexers for combining multiple light signals onto a single waveguide, demultiplexers for separating multiple light signals such that different light signals are received on different waveguides, optical couplers, optical switches, amplifiers for amplifying the intensity of a light signal, attenuators for attenuating the intensity of a light signal, modulators for modulating a signal onto a light signal, light sensors that convert a light signal to an electrical signal, and vias that provide an optical pathway for a light signal traveling through the optical device from the bottom side of the optical device to the top side of the optical device. Additionally, the optical device can optionally, include electrical components. For instance, the optical device can include electrical connections for applying a potential or current to a waveguide and/or for controlling other components on the optical device.

The laser chip 4 includes a laser waveguide 9 that guides intracavity light through a gain medium (not shown) that is the source of optical gain within the laser cavity. The laser cavity includes reflecting components 10 that form a resonant cavity. The reflecting components 10 transmit a portion of the intracavity light and reflect a portion of the intracavity light. The transmitted portion of the intracavity light serves as the laser output. As a result, the laser output exits from the laser cavity through the reflecting components. Suitable reflecting components 10 include, but are not limited to, wavelength selective optical gratings such as Bragg gratings. In some instances, the different reflecting components included in a laser cavity are each configured to reflect the same band of wavelengths or substantially the same band of wavelengths. In some instances, the different reflecting components included in a laser cavity can be configured to reflect different bands of wavelengths. Reflecting components that reflect different bands can be useful in the case of sampled gratings.

The laser waveguide 9 terminates at output facets 13. The laser waveguide can guide a laser outputs from the laser cavity to an output facet 13 when the reflecting components 10 is spaced apart from an output facet 13. Alternately, the laser cavity can terminate at one or more of the output facets.

The laser chip 4 includes lateral sides 11 between a top side (not shown) and a bottom side 12. The laser waveguide 9 is arranged such that each of the laser outputs crosses the same lateral side 11. For instance, each of the output facets 13 can be positioned along the same lateral side of the laser chip. As a result, each of the laser outputs crosses the same lateral side 11 upon exiting from the laser chip.

The laser cavity of FIG. 1A is curved along its length, however, the laser cavity can be constructed so as to have one or more straight regions. For instance, the laser cavity of FIG. 1B includes a laser wavguide that has straight regions. The straight regions are optically located between the output ports 6 and a curved region of the laser waveguide 9. One or more of the reflecting components 10 can be positioned on the straight region of the laser waveguide 9 without being positioned on the curved portion of the laser waveguide 9. Alternately, one or more of the reflecting components 10 can be positioned on a curved region of the laser waveguide 9 and one or more of the straight regions of the laser waveguide 9.

The exit direction for each laser output (the direction of propagation of the light in the laser waveguide 9 at an output facet 13) is perpendicular or substantially perpendicular to the lateral dimension (dimension evident in FIG. 1A and FIG. 1B) of the output facet 13. As a result, an anti-reflective coating 14 can optionally be positioned over the output facets 13 in order to reduce the effects of back reflection. The anti-reflective coating 14 need not be limited to the output facets 13. For instance, the anti-reflective coating 14 can extend across the portion of a lateral side 11 located between the output facets 13. For instance, the anti-reflective coating 14 can cover a lateral side 11 of the laser chip 4 as shown in FIG. 1A and FIG. 1B. Suitable anti-reflective coatings 14 include, but are not limited to, SiO₂, SiN, and HfO₂, Al₂O₃.

The exit direction need not be perpendicular or substantially perpendicular to the lateral dimension of the output facet 13. As an example, FIG. 1C is a top view of a laser cavity where the laser waveguide 9 is constructed such that the exit direction at each output facet 13 is not perpendicular to the lateral dimension of either of the output facets 13. Suitable angles between the exit direction and the lateral dimension of the output facet 13 include but are not limited to, angles between 80° and 89°, and angles between 80° and 85°. In some instance, one or more of the output facets 13 are perpendicular or substantially perpendicular relative to a top side of the laser chip 4 and/or a bottom side of the laser chip 4 while also being non-perpendicular relative to the exit direction. The non-perpendicularity between the output facet 13 and the exit direction can reduce the effects of back reflection. In some instances, the reduction in the effects of back reflection can be sufficient to reduce or eliminate the need for an anti-reflective coating 14. As a result, the non-perpendicularity between the output facet 13 and the exit direction can be used in conjunction with an anti-reflective coating 14 over one or more of the output facets 13 or can be used without an anti-reflective coating 14.

There may be refraction of the laser output as a result of the non-perpendicularity between the output facet 13 and the exit direction. As a result, the exit direction may be different from the direction at which an output signal travels away from an output facet 13. In order to reduce or minimize optical loss, the angle of a waveguide 7 on the optical device relative to the direction of the output signal can optionally be selected such that the direction is perpendicular to a facet of the waveguide 7. As a result, a lateral dimension of a facet on the waveguide 7 need not be parallel to a lateral side of the optical device.

The laser cavities illustrated in FIG. 1A through FIG. 1C are Distributed Bragg Reflector (DBR) lasers; however, the above laser cavities can be Distributed Feedback (DFB) lasers. For instance, FIG. 1D is a top view of the optical system of FIG. 1B that includes a laser chip 4 that is modified to include a Distributed Feedback (DFB) laser cavity.

In FIG. 1A and FIG. 1B, the exit direction for each laser output is parallel. As a result, the laser waveguide 9 is constructed such that the angle between the exit directions of the laser outputs is zero. However, in FIG. 1C, the angle between the exit direction of the laser outputs is greater than zero. As a result, the angle between the exit directions can have non-zero values. For instance, FIG. 1E is a top view of an optical system that includes a laser chip 4 having a 90° angle between the exit directions of the laser outputs. Suitable angles between the exit directions include angles less than 179°, 135°, or 90° and/or greater than or equal to 0°, 10°, or 45°.

The laser waveguides 9 illustrated above use curves in order to achieve the desired direction of light, however, the laser waveguide can make use of other structures to achieve the desired directions for light propagation. For instance, the laser cavity and/or laser waveguide can include reflectors such as mirrors positioned at one or more locations along the length of the laser waveguide 9. As an example, FIG. 1F is a top view of the optical system of

FIG. 1B that includes a laser chip 4 having a laser waveguide 9 that includes two mirrors arranged so as to provide a zero angle between the exit direction of the intracavity light.

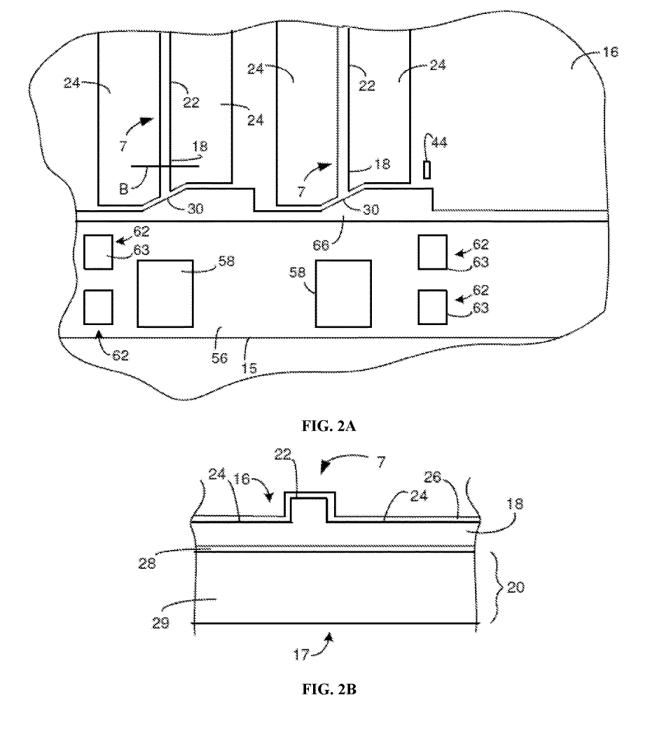

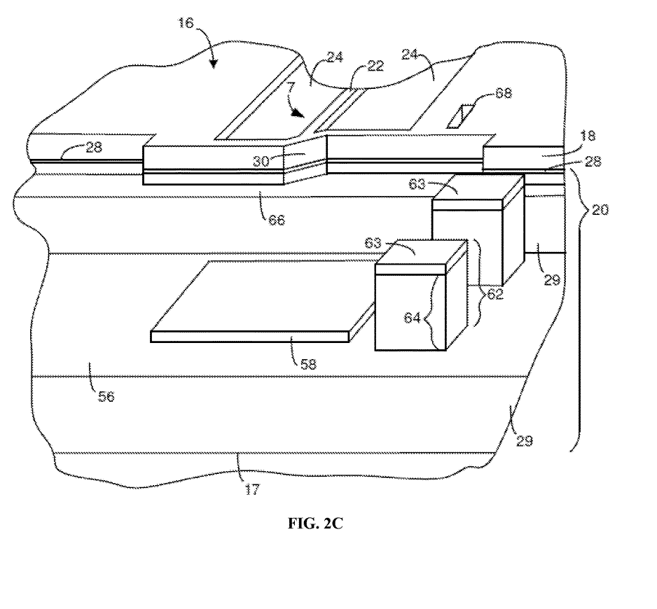

FIG. 2A through FIG. 2C illustrate an optical device that is suitable for use in the optical system of FIG. 1A through FIG. 1F. FIG. 2A is a top view of the portion of the optical device that is configured to be attached to the laser chip. FIG. 2B is a cross section of the optical device taken along the line labeled B in FIG. 2A. FIG. 2C is a perspective view of a portion of the optical device shown in FIG. 2A.

The optical device is within the class of optical devices known as planar optical devices. These optical devices typically include one or more waveguides 7 immobilized relative to a substrate or a base. The direction of propagation of light signals along the waveguides 7 is generally parallel to a plane of the optical device. Examples of the plane of the optical device include the top side of the base, the bottom side of the base, the top side of the substrate, and/or the bottom side of the substrate. The illustrated optical device includes lateral sides 15 (or edges) extending from a top side 16 to a bottom side 17. The propagation direction of light signals along the length of the waveguides 7 on a planar optical device generally extends through a lateral side 15 of the optical device. The top side and the bottom side of the optical device are non-lateral sides.

The waveguides 7 are defined in a light-transmitting medium 18 positioned on a base 20. For instance, a portion of the waveguide 7 is partially defined by a ridge 22 extending upward from a slab region of the light-transmitting medium as shown in FIG. 1B. In some instances, the top of the slab region is defined by the bottom of trenches 24 extending partially into the light-transmitting medium 18 or through the light-transmitting medium 18. Suitable light-transmitting media include, but are not limited to, silicon, polymers, silica, SiN, GaAs, InP and LiNbO₃. One or more cladding layers 26 are optionally positioned on the light-transmitting medium 18 as shown in FIG. 2B. The cladding layers are not shown in FIG. 2A or FIG. 2C in order to clarify the relationship between the other components on the optical device. The one or more cladding layers can serve as a cladding for the waveguide 7 and/or for the optical device. When the light-transmitting medium 18 is silicon, suitable cladding layers include, but are not limited to, polymers, silica, SiN, GaAs, InP and LiNbO₃.

The portion of the base 20 adjacent to the light-transmitting medium 18 is configured to reflect light signals from the waveguide 7 back into the waveguide 7 in order to constrain light signals in the waveguide 7. For instance, the portion of the base 20 adjacent to the light-transmitting medium 18 can be a light insulator 28 with a lower index of refraction than the light-transmitting medium 18. The drop in the index of refraction can cause reflection of a light signal from the light-transmitting medium 18 back into the light-transmitting medium 18. The base 20 can include the light insulator 28 positioned on a substrate 29. As will become evident below, the substrate 29 can be configured to transmit light signals. For instance, the substrate 29 can be constructed of a medium that is different from the light-transmitting medium 18 or the same as the light-transmitting medium 18. In one example, the optical device is constructed on a silicon-on-insulator wafer. A silicon-on-insulator wafer includes a silicon layer that serves as the light-transmitting medium 18. The silicon-on-insulator wafer also includes a layer of silica positioned on a silicon substrate. The layer of silica can serve as the light insulator 28 and the silicon substrate can serve as the substrate 29.

A recess extends into the base 20 to form a laser platform 56. A contact pad 58 positioned on the laser platform 56 can be employed for providing electrical communication with a laser on the laser platform 56. One or more stops 62 extend upward from the laser platform 56. For instance, FIG. 8 illustrates two stops 62 extending upward from the laser platform 56. The stops 62 include a cladding 63 positioned on a base portion 64. The substrate 29 can serve as the base portion 64 of the stops 62 and the stop 62 can exclude the light insulator 28 or be made of the same material as the light insulator 28. The portion of the substrate 29 included in the stops 62 can extend from the laser platform 56 up to the level of the light insulator 28. For instance, the stops 62 can be formed by etching through the light insulator 28 and using the underlying substrate 29 as an etch-stop. The cladding 63 can then be formed on the first light-transmitting medium 18 at the same time the cladding 63 is formed on the base portion 64 of the stops 62.

A secondary platform 66 is positioned between the waveguide facet 30 and the laser platform 56. The secondary platform 66 is elevated relative to the laser platform 56. For instance, the secondary platform 66 can be above the laser platform 56 and at or below the level of the light insulator 28. FIG. 2C shows the secondary platform 66 below the level of the light insulator 28; however, the top of the substrate 29 can serve as the secondary platform 66. The secondary platform 66 can be etched at a different time than the portion of the stops 62 that is defined by the substrate 29. Alternately, the secondary platform 66 can be etched concurrently with the base portion 64 of the stops 62 resulting in the secondary platform 66 and the base portion 64 of the stops 62 having about the same height above the laser platform 56.

The optical device includes one or more alignment marks 68. Suitable marks include recesses that extend into the optical device. An alignment mark 68 can extend into the first light-transmitting medium 18 and/or the base. In some instances, one or more of the alignment marks 68 extend into the secondary platform 66. FIG. 2C illustrates an alignment mark 68 extending into the first light-transmitting medium 18. During attachment of a laser to the optical device, each alignment mark 68 can be aligned with one or more secondary alignment marks on a laser in order to achieve horizontal alignment of the laser relative to the optical device.

An optical device according to FIG. 2A through FIG. 2C can be generated by fabrication or purchase from a supplier. For instance, the optical device can be fabricated by etching the ridge for the waveguides 7. The secondary platform 66 and the base portion 64 of the stops 62 can be etched by etching through the first light transmitting medium using an etch for which the light insulator 28 acts as an etch stop followed by etching through the light insulator 28 using an etch for which the substrate 29 acts as an etch stop. The alignment marks 68 can be etched into the first light-transmitting medium 18 and the cladding 63 can be deposited on the first light-transmitting medium 18 and on the base portion 64 of the stops 62. Additional components such as the contact pads and other electrical components can then be formed on the optical device. An additional etch can be used to form the secondary platform 66 below the level of the light insulator 28 (i.e. etch into the substrate 29) but without etching the base portion 64 of the stops 62.

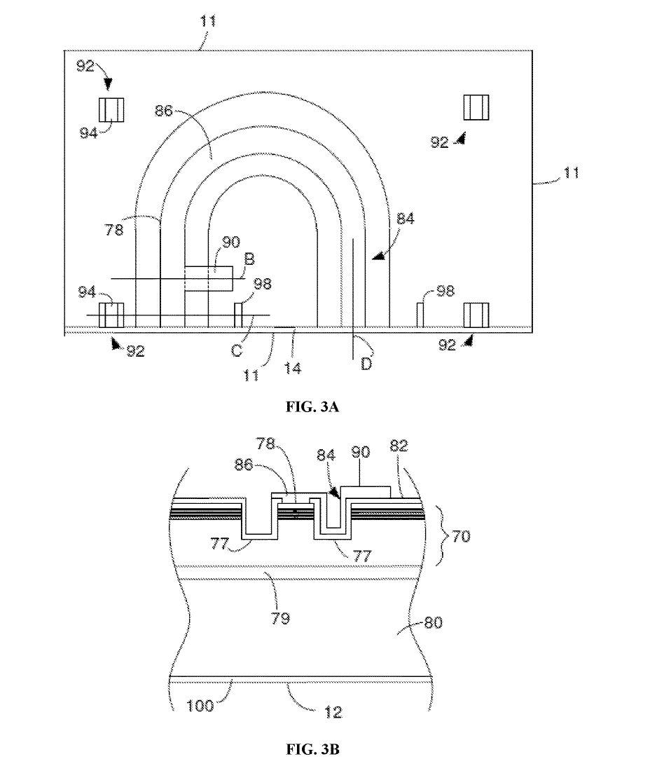

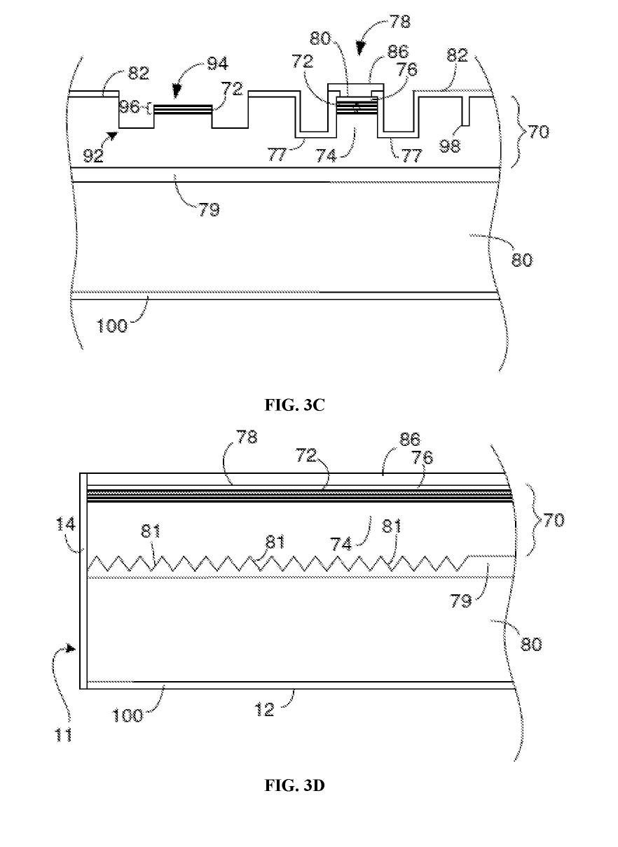

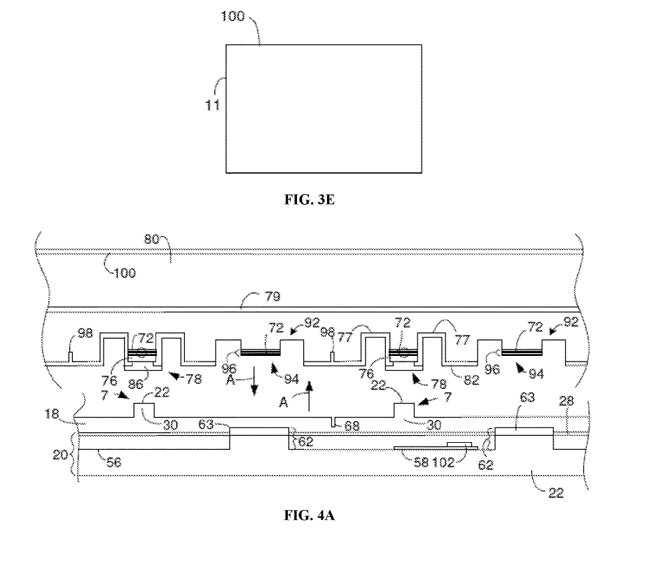

FIG. 3A through FIG. 3E illustrate a laser chip that is suitable for use with an optical device constructed according to FIG. 2A through FIG. 2C. FIG. 3A is a top view of the laser chip. FIG. 3B is a cross-section of the laser chip shown in FIG. 3A taken along the line labeled B in FIG. 3A. FIG. 3C is a cross-section of the laser chip shown in FIG. 3A taken along the line labeled C in FIG. 3A. FIG. 3D is a cross-section of the laser chip shown in FIG. 3A taken along the line labeled D in FIG. 3A. FIG. 3E is a bottom view of the laser chip shown in FIG. 3A.

One or more of the media through which the laser waveguide guides the light can be continuous along the entire length of the laser waveguide. For instance, the laser chip can include a gain medium 70 that is the source of optical gain within the laser. The gain medium 70 includes sub-layers 72 between a lower gain medium 74 and an upper gain medium 76. One or more components selected from the group consisting of the gain medium 70, one or more sub-layers 72, lower gain medium 74 and upper gain medium 76 can be continuous along the length of the laser waveguide. As an example, one or more components selected from the group consisting of the gain medium 70, one or more sub-layers 72, lower gain medium 74 and upper gain medium 76 can extend continuously from one of the output facets 13 to another of the output facets 13.

The lower gain medium 74 and the upper gain medium 76 can be the same or different. Suitable lower gain media include, but are not limited to, materials that combine one or more group III elements with one or more group IV elements such as InP, InGaAsP, GaSb, GaN, GaAs, AlₓGa₍₁₋ₓ₎As where x is 0.1 to 0.4 and combinations thereof. Suitable upper gain media include, but are not limited to, materials that combine one or more group III elements with one or more group IV elements such as InP, InGaAsP, GaSb, GaN, GaAs, AlₓGa₍₁₋ₓ₎As where x is 0.1 to 0.4 and combinations thereof. In one example, the lower gain medium 74 and the upper gain medium 76 are each GaAs. As will be discussed in more detail below, each of the sub-layers 72 can have a different composition of a material than the one or more sub-layers 72 that contact that sub-layer 72. In some instances, each of the sub-layers 72 has a different chemical composition. Each sub-layer 72 or a portion of the sub-layers 72 can include or consists of two or more components selected from a group consisting of In, P, Gs, and As. In some instances, the upper gain medium 76 is optional. In one example, the sub-layers 72 alternate GaAs with AlₓGa₍₁₋ₓ₎As where x is 0.1 to 0.4. In another example, the lower gain medium 74 and the upper gain medium 76 are each GaAs and the sub-layers 72 alternate GaAs with AlₓGa₍₁₋ₓ₎As where x is 0.1 to 0.4.

Trenches 77 extend into the gain medium 70 so as to form a laser ridge 78 in the gain medium 70. The ridge 78 defines the laser waveguide 9 on the laser chip. All or a portion of the sub-layers 72 can be included in the laser ridge 78. In some instances, one or more components selected from the group consisting of the gain medium 70, one or more sub-layers 72, lower gain medium 74 and upper gain medium 76 is continuously positioned in the ridge for the length of the laser waveguide. As an example, one or more components selected from the group consisting of the gain medium 70, one or more sub-layers 72, lower gain medium 74 and upper gain medium 76 is positioned in the ridge continuously from one of the output facets 13 to another of the output facets 13.

The laser chip includes a grating layer positioned so as to interact with the intracavity light resonating in the laser cavity. For instance, FIG. 3B through FIG. 3E illustrate a grating layer 79 between the gain medium and a substrate 80. The grating layer 79 can be formed so as to act as the one or more reflecting components 10 shown in FIG. 1A through FIG. 1F. For instance, the grating layer 79 can be patterned so as to include one or more optical gratings that act as the source of resonation in the laser cavity. As is evident from FIG. 3D, recesses 81 can extend into the grating layer 79 so as to form the optical grating. As is known in the optical grating arts, the dimensions of the recesses 81, shape of the recesses 81, spacing of the recesses 81, and total number recesses 81 can be adjusted so as to provide the laser cavity with the desired optical characteristics such as wavelength and transmission percentage. Additionally or alternately, when all or a portion of the recesses are arranged periodically, the period can also be adjusted so as to provide the laser cavity with the desired optical characteristics such as wavelength and transmission percentage. FIG. 3D shows the optical grating located in only a portion of the laser cavity as would be suitable for use in Distributed Bragg Reflector (DBR) laser cavities. However, the optical grating can be formed over the entire laser cavity to provide a Distributed Feedback (DFB) lasers as shown in FIG. 1D.

Suitable materials for the grating layer 79 include, but are not limited to, InGaAs and/or InGaAsP. In some instances, the grating layer 79 has a lower index of refraction than the lower gain medium 74. Suitable materials for the substrate 80 include, but are not limited to, InP and/or GaAs. The grating can be patterned in the grating layer 79 using techniques such as etching, holography and e-beam lithography. After patterning the grating layer 79, the lower gain medium 74 can be formed over the grating layer 79 with techniques such as Metalorganic vapour phase epitaxy (MOVPE), metalorganic chemical vapour deposition (MOCVD), and/or molecular beam epitaxy (MBE).

Although FIG. 3C shows the grating layer 79 under the laser ridge, the grating layer 79 can be positioned in other locations where a grating patterned into the grating layer 79 interacts with the intracavity light. For instance, the grating layer 79 can be located over the sub-layers 72 and/or in the laser ridge. As an example, the grating layer 79 can be located between the sub-layers 72 and the contact region 86 of the first electrical conductor 84 or between the upper gain medium 76 and the contact region 86. In some instances, the grating layer 79 is located over the laser waveguide 9 and under the laser waveguide 9.

A laser cladding 82 is positioned on the gain medium 70. A first electrical conductor 84 positioned on the cladding includes a contact region 86 that extends through an opening in the laser cladding 82 into contact with a top of the laser ridge 78. The first electrical conductor 84 extends from the contact region 86 across a trench 77 to a contact pad 90. The contact pad 90 can be employed to apply electrical energy to the laser.

The laser cavity can be positioned adjacent to one or more alignment trenches 92 and/or between alignment trenches 92. For instance, FIG. 3A illustrates the laser cavity between alignment trenches 92. A secondary stop 94 extends upward from the bottom of the alignment trench 92. The secondary stop 94 can include an alignment layer 96 on top of the lower gain medium 74. The alignment layer 96 can include or consist of one or more sub-layers 72 in contact with one another. The choice of the depth of the alignment layer 96 below the bottom surface of the laser chip determines the vertical alignment between the lasers and the waveguide facets 30.

Although FIG. 3A through FIG. 3D illustrate a secondary stop 94 extending upward from a bottom of the alignment trench 92 such that walls of the secondary stop 94 are spaced apart from walls of the alignment trench 92, the bottom of the alignment trench 92 can be substantially flat and one or more alignment layers 96 on the bottom of the alignment trench 92 can serve as the secondary stop 94. However, an embodiment having walls of the secondary stop 94 spaced apart from walls of the alignment trench 92 may be preferred to reduce etch induced inconsistencies on the tops of the secondary stops 94.

One or more secondary alignment recesses 98 can extend into the gain medium 70.

An electrically conducting medium 100 can be positioned under the gain medium 70. The electrically conducting medium 100 can be used as a ground for the laser cavity when the electronics apply electrical energy to the laser.

The laser chip can be generated by purchase from a supplier and/or fabricated.

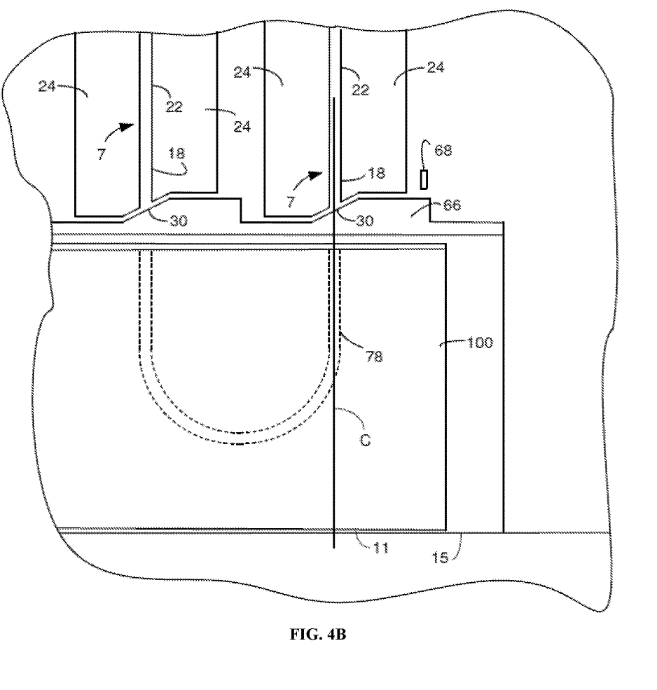

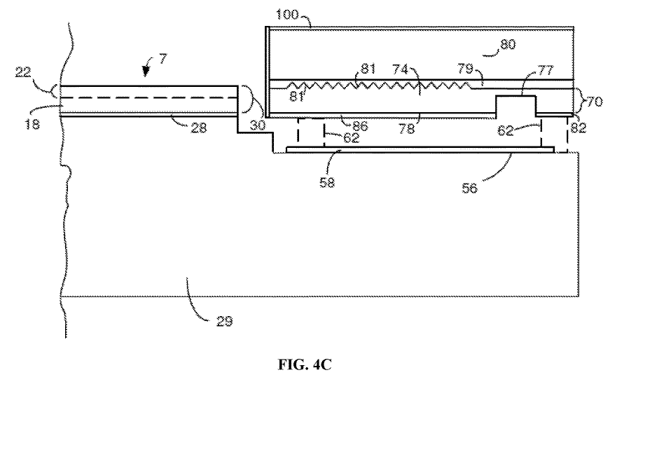

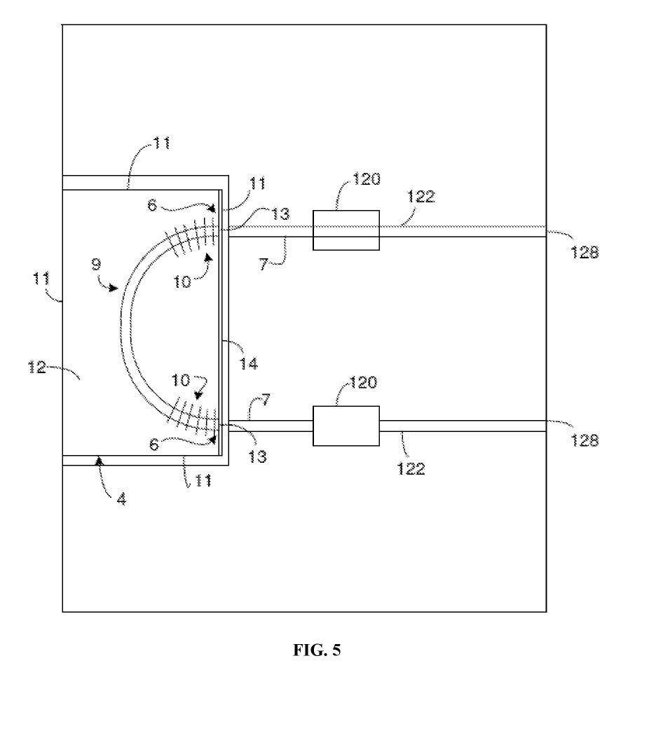

FIG. 4A through FIG. 4C illustrate assembly of the optical system using an optical device constructed according to FIG. 2A through FIG. 2C and a laser chip constructed according to FIG. 3A through FIG. 3E. The optical device illustrated in FIG. 4A does not show either a cross-sectional view or a side view. Instead, the view of the optical device shows the relative positions of different features of the optical device when looking at a side view of the optical device. In contrast, the laser chip illustrated in FIG. 4A is a cross-sectional view of the laser chip such as the cross section of FIG. 3C. FIG. 4B and FIG. 4C illustrate the optical device of FIG. 4A and the laser of FIG. 4A assembled into an optical system. FIG. 4B is a top view of the assembled system. As is evident from FIG. 4A, the laser is attached to the optical device in a flip-chip configuration. As a result, the substrate 80 and electrically conducting medium 100 are positioned over the laser waveguide 9. As a result, the laser waveguide 9 would not normally be visible in the top view of FIG. 4B. In order to illustrate the relative positions of the components of the system, the location of the laser ridge 78 is shown by the dashed line in FIG. 4B. FIG. 4C is a cross section of the system shown in FIG. 4B taken along the line labeled C in FIG. 4B. Because of the location of the cross section, the stops 62 would not normally be evident in the cross section of FIG. 4C, however, dashed lines are used to show the location of the stops 62 behind the features shown in FIG. 4C.

The optical system can be assembled by moving the optical device and the laser chip toward one another as indicated by the arrows labeled A in FIG. 4A. The alignment marks 68 and the secondary alignment recesses 98 are positioned such that they can be aligned with one another during assembly of the optical system. The alignment of these features achieves horizontal alignment of the laser and the optical device. For instance, alignment of these features achieves horizontal alignment of the waveguide facet 30 with the output facet 13. Additionally, each of the stops 62 on the optical device is aligned with one of the secondary stops 94 on the laser.

As is evident from FIG. 4A, each of the stops 62 on the optical device meets one of the secondary stops 94 on the laser. As a result, the vertical movement of the optical device and the laser toward one another is limited by the stops 62 butting against the secondary stops 94. Accordingly, the height of the laser mode relative to the waveguides 7 is a function of the thickness of the alignment layer 96. For instance, increasing the thickness of the alignment layer 96 can elevate the laser mode relative to the waveguide 7. As a result, the alignment layer 96 is formed with a thickness that places the laser mode in vertical alignment with the waveguide facet 30.

The thickness of the alignment layer 96 can be controlled by removing sub-layers from an alignment layer precursor. For instance, before removal of any sub-layers from alignment layer precursor, each of the sub-layers 72 in the alignment layer precursor corresponds to a sub-layer 72 in the laser ridge 78. For instance, each of the sub-layers 72 in the alignment layer precursor can have the same chemical composition of one of the sub-layers 72 in the laser ridge 78. Additionally or alternately, each of the sub-layers 72 in the alignment layer alignment layer precursor can be at the same height as the corresponding sub-layers 72 in the laser ridge 78 and/or have the same thickness as the corresponding sub-layers 72 in the laser ridge 78. Since the sub-layers 72 in the secondary stop 94 each corresponds to a sub-layer 72 in the laser ridge 78 and the sub-layers 72 in the laser ridge 78 define the position of the laser mode in the laser ridge 78, the location of each sub-layer 72 in the secondary stop 94 relative to the laser mode is known.

Each of the sub-layers 72 in an alignment layer 96 can have a different chemical composition from the one or more immediately neighboring sub-layers 72 and/or each of the sub-layers 72 can have a different chemical composition. For instance, the sub-layers 72 can include or consist of a dopant in the gain medium 70. Each sub-layer 72 can have a different dopant and/or dopant concentration from the one or more neighboring sub-layers 72 and/or each of the sub-layers 72 can have a different dopant and/or dopant concentration. As an example, each sub-layer 72 can includes or consists of two or more components selected from a group consisting of In, P, Ga, and As and different sub-layers 72 can have the elements present in different ratios. In another example, each sub-layer 72 includes or consists In, P and none, one, or two components selected from a group consisting of Ga, and As and each of the different sub-layers 72 has these components in a different ratio. Examples of materials that include multiple elements selected from the above group include different compositions of InP with or without dopants such as In₍₁₋ₓ₎GaₓAs_{y}P_{(1-y)} where x is from 0 to 1, y is from 0 to 1, and x+y=1 or In—Ga—As—P. Additionally, there may be other sub-layers 72 present to compensate for stress due to lattice mismatch between the compositions of the different sub-layers 72. The location of the laser mode in the laser ridge 78 is defined by the different sub-layers 72 as a result of the refractive indices of the different compositions.

The different compositions of the sub-layers 72 in an alignment layer precursor can be employed to control the thickness of the alignment layer 96. For instance, one or more sub-layers 72 can be removed from the alignment layer precursor until the alignment layer 96 has the desired thickness. The one or more sub-layers 72 can be removed by etching. The etch can be chosen such that the sub-layer 72 that will serve as the uppermost sub-layer 72 of the completed alignment layer 96 acts as an etch stop. As a result, the thickness of the alignment layer 96 can be controlled by selecting the sub-layer 72 that will serve as the etch stop and then selecting the appropriate etch. Further, since the height of each sub-layer 72 relative to the laser mode is fixed, the ability to control the thickness of the alignment layer 96 also allows the height of the alignment layer 96 relative to the laser mode to be both known and controlled.

In some instances, before any of the sub-layers 72 are removed from the alignment layer precursor, the alignment layer 96 can have more than 3 sub-layers 72, more than 5 sub-layers 72, more than 7 sub-layers 72, or more than 9 sub-layers 72. Accordingly, the laser ridge 78 can have more than 3 sub-layers 72, more than 5 sub-layers 72, more than 7 sub-layers 72, or more than 9 sub-layers 72.

FIG. 4A shows a solder pad 102 positioned on the contact pad 58 on the laser platform 56. Although not evident from FIG. 4A through FIG. 4C, at least a portion of the solder pad 102 is aligned with the contact pad 90 (FIG. 3A) and can contact the contact pad 90 upon assembly of the system. As a result, the solder pad 102 can provide electrical communication between the contact pad 58 on the laser platform 56 and the contact pad (not shown in FIG. 4A through FIG. 4C) on the laser chip. The laser outputs can be generated by applying an electrical signal to the gain medium 70 so as to cause an electrical current to flow through the gain medium 70. Accordingly, electronics can generate the laser outputs from the laser cavity by applying an electrical signal to the laser chip so as to generate a potential difference between the contact pad 58 and the electrically conducting medium 100. The electrical signal applied by the electronics serves to pump the laser. The solder pad 102 can also immobilize the laser relative to the optical device once the laser is positioned on the optical device.

The system can be assembled by placing the laser chip on the optical device. In an optical device constructed according to FIG. 2A through FIG. 2C, the height of the stops 62 can be determined from the fabrication process or can be measured. The height of the stops 62 can be combined with the desired height of the laser modes to determine the alignment layer 96 thickness needed to achieve the desired vertical alignment. The sub-layer 72 that would serve as the upper-most sub-layer 72 in an alignment layer 96 having the desired thickness can then be identified. An etch or serial combination of etches that would expose the identified sub-layer 72 without detrimentally etching the identified sub-layer 72 can also be identified. The identified etches can then be performed so as to remove one or more sub-layers 72 above the identified sub-layer 72 and expose the identified sub-layer 72. The laser can then be positioned on the optical device with the stops 62 extending into the alignment trenches 92 and contacting (or butting against) the secondary stops 94.

The laser waveguide and laser cavity disclosed above can have a construction other than the construction illustrated in FIG. 3A through FIG. 4C. Suitable laser chips for use with the disclosed laser waveguide and laser cavity include, but are not limited to, semiconductor lasers, and solid state lasers. In some instances, laser waveguide and laser cavity disclosed above are built on a laser chip that includes, consists of, or consists essentially of doped and/or undoped semiconductors and one or more electrical conductors for applying electrical pumping energy to the semiconductors.

A variety of different optical devices can be used in the optical systems disclosed above. As an example, FIG. 5 is a combination of a schematic and a block diagram having a laser chip on an optical device. The system can operate as a transmitter. For instance, the waveguides 7 on the optical device each guide one of the output signals from the laser chip to a modulator 120. Electronics operate the modulators 120 so as to modulate an output signal and output a modulated signal. The device includes modulated waveguides 122 the each guides a different one of the modulated signals to an output facet 128 through which the output of the device exits from the device. The laser chip illustrated in FIG. 5 is in accordance with the laser chip of FIG. 1A, however, other laser chip constructions disclosed herein can be used in conjunction with the optical device.

Examples of modulator constructions that are suitable for use in conjunction with silicon-on-insulator wafers can be found in U.S. patent application Ser. No. 12/653,547, filed on Dec. 15, 2009, entitled “Optical Device Having Modulator Employing Horizontal Electrical Field,” and U.S. patent application Ser. No. 13/385,774, filed on Mar. 4, 2012, entitled “Integration of Components on Optical Device,” each of which is incorporated herein in its entirety. U.S. patent application Ser. Nos. 12/653,547 and 13/385,774 also provide additional details about the fabrication, structure and operation of these modulators. In some instances, the modulator is constructed and operated as shown in U.S. patent application Ser. No. 11/146,898; filed on Jun. 7, 2005; entitled “High Speed Optical Phase Modulator,” and now U.S. Pat. No. 7,394,948; or as disclosed in U.S. patent application Ser. No. 11/147,403; filed on Jun. 7, 2005; entitled “High Speed Optical Intensity Modulator,” and now U.S. Pat. No. 7,394,949; or as disclosed in U.S. patent application Ser. No. 12/154,435; filed on May 21, 2008; entitled “High Speed Optical Phase Modulator,” and now U.S. Pat. No. 7,652,630; or as disclosed in U.S. patent application Ser. No. 12/319,718; filed on Jan. 8, 2009; and entitled “High Speed Optical Modulator;” or as disclosed in U.S. patent application Ser. No. 12/928,076; filed on Dec. 1, 2010; and entitled “Ring Resonator with Wavelength Selectivity;” or as disclosed in U.S. patent application Ser. No. 12/228,671, filed on Aug. 13, 2008, and entitled “Electrooptic Silicon Modulator with Enhanced Bandwidth;” or as disclosed in U.S. patent application Ser. No. 12/660,149, filed on Feb. 19, 2010, and entitled “Reducing Optical Loss in Optical Modulator Using Depletion Region;” each of which is incorporated herein in its entirety.

The above discussions disclose using a first material as an etch stop against an etch configured to etch a second material in contact with the first material. A first material acts as an etch stop when the etch is significantly more corrosive (often called more selective) of the second material than of the first material. As a result, once the etch etches through the second material to the first material, the etch rate drops. Because the etch rate drops, the importance of the etch duration drops and the etch can be executed for a period of time that ensures that the second material will be etched without significantly etching into the first material.

Additional details about the construction, operation and fabrication of the optical device, laser chip, and optical system illustrated in FIG. 1A through FIG. 4C can be found in U.S. patent application Ser. No. 12/215,693, U.S. Pat. No. 7,658,552, filed on Jun. 28, 2008, entitled “Interface Between Light Source and Optical Component,” and also in U.S. patent application Ser. No. 13/385,774, U.S. Pat. No. 8,638,485, filed on Mar. 5, 2012, entitled “Integration of Components on Optical Device,” each of which is incorporated herein in its entirety.

Suitable electronics for use with the device include, but are not limited to, firmware, hardware and software or a combination thereof. Examples of suitable electronics 47 include, but are not limited to, analog electrical circuits, digital electrical circuits, processors, microprocessors, digital signal processors (DSPs), computers, microcomputers, ASICs, and discrete electrical components, or combinations suitable for performing the required control functions. In some instances, the control electronics 47 includes a memory that includes instructions to be executed by a processing unit during performance of the control and monitoring functions.

FIG. 4A through FIG. 4C illustrate one mechanism for mounting a laser chip on an optical device, however, other mounting mechanisms can be employed. For instance, an alternative method for mounting a laser chip on an optical device is disclosed in U.S. patent application Ser. No. 08/853,104, filed on May 8, 1997, entitled “Assembly of an Optical Component and an Optical Waveguide,” now issued as U.S. Pat. No. 5,881,190, and incorporated herein in its entirety. The method of fabrication, operation, and mounting disclosed in U.S. patent spplication Ser. No. 08/853,104 can be used in conjunction with the disclosed optical device and laser chip.

Other embodiments, combinations and modifications of this invention will occur readily to those of ordinary skill in the art in view of these teachings. Therefore, this invention is to be limited only by the following claims, which include all such embodiments and modifications when viewed in conjunction with the above specification and accompanying drawings.

1. An optical system, comprising:
a laser chip including a laser cavity that produces laser outputs,
a laser waveguide guiding light through the laser cavity having multiple output facets, each of the laser outputs passing through one of the output facets,
the laser waveguide guiding the laser outputs such that an angle between an exit direction for different laser outputs is less than 180°, the exit direction for a laser output being a direction of propagation of light in the laser waveguide at one of the output facets; and
a planar optical device that receives the laser outputs from the laser chip without returning the laser outputs to the laser cavity.

2. (canceled)

3. The system of claim 1, wherein the optical device is constructed on a silicon-on-insulator wafer.

4. The system of claim 1, wherein the angle between the exit directions is less than 90°.

5. The system of claim 1, wherein the angle between the exit directions is less than 10°.

6. The system of claim 1, wherein the laser chip includes lateral sides between a top side and a bottom side and at least two of the laser outputs cross the same lateral side.

7. The system of claim 1, wherein the laser chip includes lateral sides between a top side and a bottom side and the laser chip includes an anti-reflective coating on only one of the lateral sides.

8. The system of claim 1, wherein a medium through which the laser waveguide guides the light has a chemical composition that is constant along the length of the laser waveguide.

9. The system of claim 1, wherein the laser waveguide includes a gain medium that extends from one of the facets to another one of the facets.

10. The system of claim 1, wherein the laser cavity terminates at the facets.

11. An optical system, comprising:
a laser chip including a laser cavity that produces laser outputs,
the laser chip including lateral sides between a top side and a bottom side, and
at least two of the laser outputs crossing the same lateral side of the laser chip; and
a planar optical device that receives the laser outputs from the laser chip without returning the laser outputs to the laser cavity.

12. The system of claim 11, wherein the at least two laser outputs exit the laser chip through the same lateral side of the laser chip.

13. (canceled)

14. The system of claim 11, wherein the optical device is constructed on a silicon-on-insulator wafer.

15. The system of claim 11, wherein the laser chip includes lateral sides between a top side and a bottom side and the laser chip includes an anti-reflective coating on only one of the lateral sides.

16. The system of claim 11, wherein the laser chip includes a laser waveguide that guides light through the laser cavity.

17. The system of claim 16, wherein a medium through which the laser waveguide guides the light has a chemical composition that is constant along the length of the laser waveguide.

18. The system of claim 16, wherein the laser waveguide includes a gain medium that extends from one facet of the waveguide to another facet of the waveguide.

19. The system of claim 1, wherein the optical device includes waveguides that each receives one of the laser outputs, a first one of the waveguides guiding the received laser output directly to a first optical component selected from the group consisting of an optical multiplexer, an optical demultiplexer, an optical switch, an optical amplifier, an optical attenuator, and an optical modulator.

20. The system of claim 19, wherein a second one of the waveguides guides the received laser output directly to a second optical component selected from the group consisting of a second optical multiplexer, a optical demultiplexer, an optical switch, an optical amplifier, an optical attenuator, and an optical modulator.

21. The system of claim 11, wherein the optical device includes multiple waveguides;
the laser chip is mounted on the optical device such that each of the waveguides receives one of the laser outputs from the laser chip;
a first one of the waveguides guides the received laser output directly to a first optical component selected from the group consisting of an optical multiplexer, an optical demultiplexer, an optical switch, an optical amplifier, an optical attenuator, and an optical modulator.

22. The system of claim 21, wherein a second one of the waveguides guides the received laser output directly to a second optical component selected from the group consisting of a optical multiplexer, a optical demultiplexer, an optical switch, an optical amplifier, an optical attenuator, and an optical modulator.
